(19) United States
(12) Patent Application Publication
(10) Pub. No.: US 2019/0285416 A1
(43) Pub. Date: Sep. 19, 2019

(54) ELECTRONIC NAVIGATION ASSEMBLY

(71) Applicant: Dulcelina Silva, Lowell, MA (US)

(72) Inventor: Dulcelina Silva, Lowell, MA (US)

(21) Appl. No.: 15/919,706

(22) Filed: Mar. 13, 2018

(51) Int. Cl. G01C 21/20; H05K 5/02; G06F 1/16; G08B 21/02; G08B 25/01

(52) U.S. Cl. CPC G01C 21/206; H05K 5/0243; G06F 1/163; G08B 25/016; G06F 1/1637; G06F 1/1635; G08B 21/0269; G06F 1/1656

(57) ABSTRACT

An electronic navigation assembly includes a housing, a control circuit that is positioned within the housing and a transceiver that is positioned within the housing. The transceiver is electrically coupled to the control unit and the transceiver is in wireless communication with a global positioning system (gps) thereby facilitating a physical location of the housing to be identified. A display is coupled to the housing and the display is electrically coupled to the control circuit. The display displays indicia corresponding to a physical location of the housing superimposed on a map of a selected building to assist the user with navigating the selected building. An alert is coupled to the housing and the alert is electrically coupled to the control circuit. The alert emits a visual alarm when the control circuit receives the first input to alert the user that the user is approaching a predetermined location in the building.

### CROSS-REFERENCE TO RELATED APPLICATIONS

Not Applicable

### STATEMENT REGARDING FEDERALLY SPONSORED RESEARCH OR DEVELOPMENT

Not Applicable

### THE NAMES OF THE PARTIES TO A JOINT RESEARCH AGREEMENT

Not Applicable

### INCORPORATION-BY-REFERENCE OF MATERIAL SUBMITTED ON A COMPACT DISC OR AS A TEXT FILE VIA THE OFFICE ELECTRONIC FILING SYSTEM

Not Applicable

### STATEMENT REGARDING PRIOR DISCLOSURES BY THE INVENTOR OR JOINT INVENTOR

Not Applicable

### BACKGROUND OF THE INVENTION

### (1) Field of the Invention

### (2) Description of Related Art including information disclosed under 37 CFR 1.97 and 1.98

The disclosure and prior art relates to navigation devices and more particularly pertains to a new navigation device for PURPOSE.

### BRIEF SUMMARY OF THE INVENTION

An embodiment of the disclosure meets the needs presented above by generally comprising a housing, a control circuit that is positioned within the housing and a transceiver that is positioned within the housing. The transceiver is electrically coupled to the control unit and the transceiver is in wireless communication with a global positioning system (gps) thereby facilitating a physical location of the housing to be identified. A display is coupled to the housing and the display is electrically coupled to the control circuit. The display displays indicia corresponding to a physical location of the housing superimposed on a map of a selected building to assist the user with navigating the selected building. An alert is coupled to the housing and the alert is electrically coupled to the control circuit. The alert emits a visual alarm when the control circuit receives the first input to alert the user that the user is approaching a predetermined location in the building.

There has thus been outlined, rather broadly, the more important features of the disclosure in order that the detailed description thereof that follows may be better understood, and in order that the present contribution to the art may be better appreciated. There are additional features of the disclosure that will be described hereinafter and which will form the subject matter of the claims appended hereto.

The objects of the disclosure, along with the various features of novelty which characterize the disclosure, are pointed out with particularity in the claims annexed to and forming a part of this disclosure.

### BRIEF DESCRIPTION OF SEVERAL VIEWS OF THE DRAWING(S)

The disclosure will be better understood and objects other than those set forth above will become apparent when consideration is given to the following detailed description thereof. Such description makes reference to the annexed drawings wherein:

FIG. 1 is a front perspective view of a electronic navigation assembly according to an embodiment of the disclosure.

FIG. 2 is a back phantom view of an embodiment of the disclosure.

FIG. 3 is a front view of an embodiment of the disclosure.

FIG. 4 is a perspective in-use view of an embodiment of the disclosure.

FIG. 5 is a front view of an alternative embodiment of the disclosure.

FIG. 6 is a schematic view of an embodiment of the disclosure.

### DETAILED DESCRIPTION OF THE INVENTION

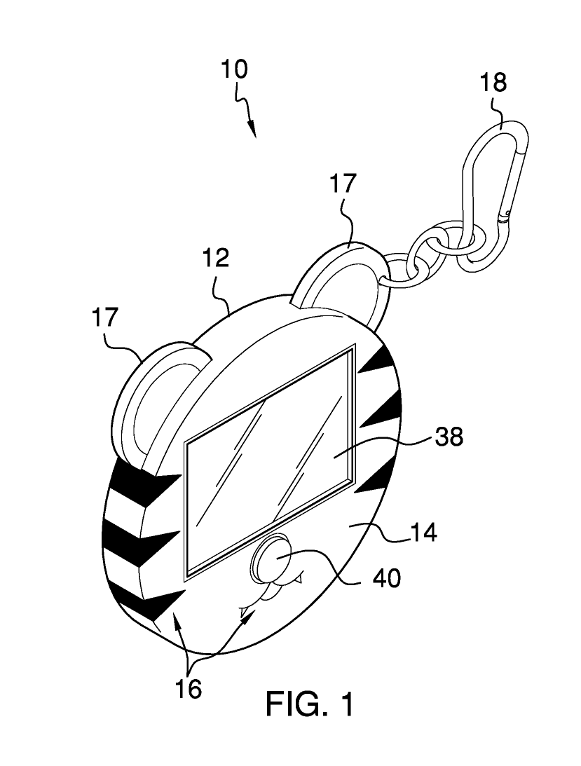

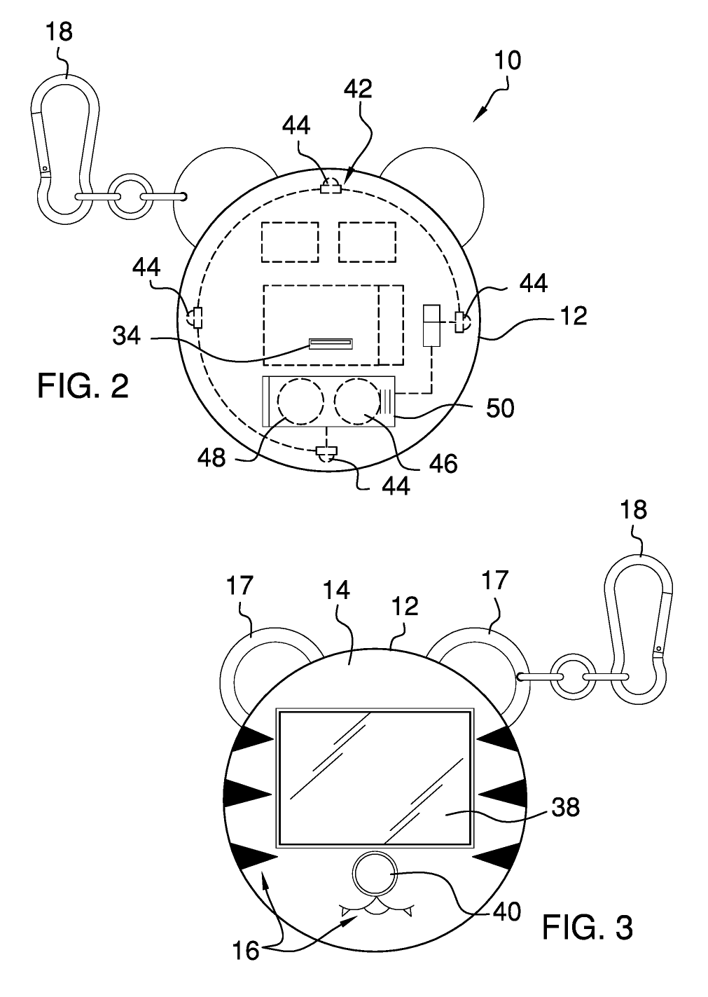

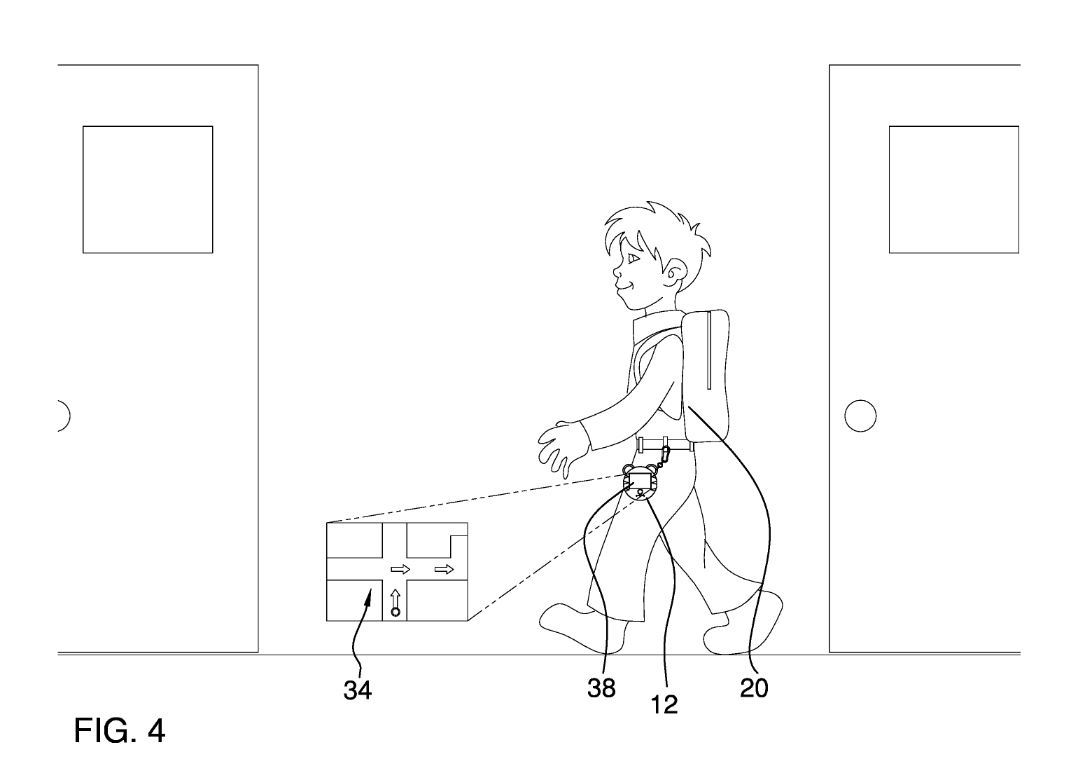

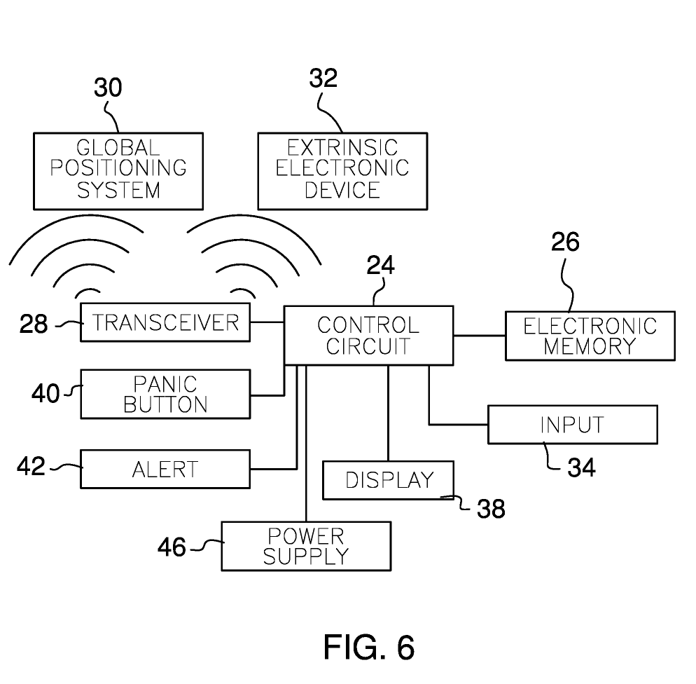

With reference now to the drawings, and in particular to FIGS. 1 through 6 thereof, a new navigation device embodying the principles and concepts of an embodiment of the disclosure and generally designated by the reference numeral 10 will be described.

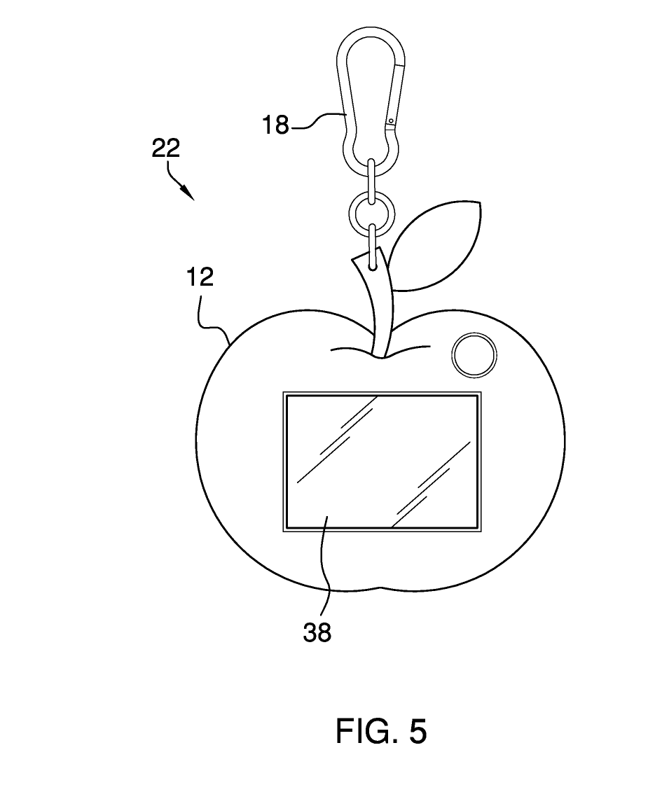

As best illustrated in FIGS. 1 through 6, the electronic navigation assembly 10 generally comprises a housing 12 that has an outer wall 14. Indicia 16 are printed on the outer wall 14 and the indicia 16 comprise shapes and images corresponding to a face of an animal such as a tiger, a bear and other animals that appeal to children. Ears 17, such as bear ears or tiger ears, may be coupled to the outer wall 14 of the housing 12 to enhance the animal appearance of the housing 12. A clasp 18 is coupled to the housing 12 and the clasp 18 releasably engages an article of clothing to retain the housing 12 on a user 20. The clasp 18 may comprise a D-ring, a lobster claw clasp 18 and any other type of releasable clasp. Additionally, the clasp 18 may be attached to the housing 12 via a sequence of chain links, a cable and any other type of flexible coupling. The article of clothing may be a belt loop on a pair of pants or the like and the user 20 may be an autistic child or other developmentally disabled individual. In an alternative embodiment 22 as shown in FIG. 5, the outer wall 14 of the housing 12 may be structured to resemble a fruit, such as an apple or the like.

A control circuit 24 is positioned within the housing 12 and an electronic memory 26 is positioned within the housing 12. The electronic memory 26 is electrically coupled to the control circuit 24 and the electronic memory 26 may comprise ROM memory or other miniaturized, electronic memory 26. A transceiver 28 is positioned within the housing 12 and the transceiver 28 is electrically coupled to the control unit. The transceiver 28 is in wireless communication with a global positioning system 30 thereby facilitating a physical location of the housing 12 to be identified. Moreover, the transceiver 28 is in wireless communication with an extrinsic electronic device 32 assigned to a caregiver. The extrinsic electronic device 32 may be a smart phone, a laptop computer and any other electronic device with wireless communication abilities.

An input 34 is coupled to the housing 12 and the input 34 is electrically coupled to the control circuit 24. The input 34 is placed in selective electrical communication with an electronic database 36 for downloading a data into the electronic memory 26. The data may include a map of a selected building, pre-determined locations in the selected building and a daily schedule pertaining to the predetermined locations in the building. Moreover, the control circuit 24 receives a first input 34 when the transceiver 28 determines the housing 12 has moved within a trigger distance of the predetermined locations in the building. The input 34 may comprise a usb port or the like and the input 34 may receive a usb cable. The selected building may be a public school that the user 20 attends, a hospital, and any other large, institutional building that could be confusing or overwhelming for the user 20.

A display 38 is coupled to the housing 12 and the display 38 is electrically coupled to the control circuit 24. The display 38 displays indicia 39 corresponding to a location of the housing 12 superimposed on the map of the selected building. In this way the display 38 assists the user 20 with navigating the selected building. The display 38 may be an LCD or the like and the display 38 is positioned on the outer wall 14 of the housing 12.

A panic button 40 is coupled to the housing 12 and the panic button 40 is manipulated when the user 20 becomes lost or disoriented in the building. The panic button 40 is electrically coupled to the control circuit 24 and the control circuit 24 receives a second input 34 when the panic button 40 is manipulated. The transceiver 28 communicates the physical location of the housing 12 to the extrinsic electronic device 32 assigned to the caregiver when the control circuit 24 receives the second input 34. In this way the panic button 40 allows the caregiver to locate and assist the user 20 when the user 20 manipulates the panic button 40.

An alert 42 is coupled to the housing 12 and the alert 42 is electrically coupled to the control circuit 24. The alert 42 emits a visual alarm when the control circuit 24 receives the first input 34. In this way the alert 42 notifies the user 20 that the user 20 is approaching one of the predetermined locations. The visual alarm comprises a plurality of light emitters 44 that are each coupled to the housing 12. Each of the light emitters 44 emits light outwardly from the housing 12 when the alert 42 is turned on and each of the light emitters 44 may comprise an LED or the like.

A power supply 46 is positioned within the housing 12 and the power supply 46 is electrically coupled to the control circuit 24. The power supply 46 comprises at least one battery 48. A battery cover 50 is removably coupled to the housing 12 and the power supply 46 is positioned beneath the battery cover 50.

In use, the input 34 is electrically coupled to the electronic database 36 to download the maps of the selected building, the pre-determined locations and the schedule. The clasp 18 is coupled to the article of clothing and the user 20 views the display 38 when the user 20 is navigating the selected building. The display 38 displays the user's 20 location on the map of the selected building thereby facilitating the user 20 to navigate between the pre-determined locations. Additionally, the alert 42 is turned on when the user 20 moves within the trigger distance of the pre-determined locations to assure the user 20 that the user 20 is correctly navigating the building. The user 20 may depress the panic button 40 at any time that the user 20 becomes lost, disoriented or uncomfortable thereby allowing the caregiver to receive the physical location of the user 20 and to assist the user 20.

With respect to the above description then, it is to be realized that the optimum dimensional relationships for the parts of an embodiment enabled by the disclosure, to include variations in size, materials, shape, form, function and manner of operation, assembly and use, are deemed readily apparent and obvious to one skilled in the art, and all equivalent relationships to those illustrated in the drawings and described in the specification are intended to be encompassed by an embodiment of the disclosure.

Therefore, the foregoing is considered as illustrative only of the principles of the disclosure. Further, since numerous modifications and changes will readily occur to those skilled in the art, it is not desired to limit the disclosure to the exact construction and operation shown and described, and accordingly, all suitable modifications and equivalents may be resorted to, falling within the scope of the disclosure. In this patent document, the word “comprising” is used in its non-limiting sense to mean that items following the word are included, but items not specifically mentioned are not excluded. A reference to an element by the indefinite article “a” does not exclude the possibility that more than one of the element is present, unless the context clearly requires that there be only one of the elements.

I claim:

1. An electronic navigation assembly for assisting a disabled user to navigate a building, said assembly comprising:
a housing, said housing having an outer wall having indicia being printed thereon, said indicia comprising shapes and images corresponding to a face of an animal such as a tiger, a bear and other animals that appeal to children;
a control circuit being positioned within said housing;
a transceiver being positioned within said housing, said transceiver being electrically coupled to said control unit, said transceiver being in wireless communication with a global positioning system (gps) thereby facilitating a physical location of said housing to be identified;
a display being coupled to said housing, said display being electrically coupled to said control circuit, said display displaying indicia corresponding to a physical location of said housing superimposed on a map of a selected building wherein said display is configured to assist the user with navigating the selected building; and
an alert being coupled to said housing, said alert being electrically coupled to said control circuit, said alert emitting a visual alarm when said control circuit receives said first input to alert the user that the user is approaching a predetermined location in the building.

2. The assembly according to claim 1, further comprising a clasp being coupled to said housing wherein said clasp is configured to engage an article of clothing to retain said housing on a user.

3. The assembly according to claim 2, further comprising an electronic memory being positioned within said housing, said electronic memory being electrically coupled to said control circuit.

4. The assembly according to claim 1, wherein said transceiver is in wireless communication with an extrinsic electronic device assigned to a caregiver.

5. The assembly according to claim 4, further comprising an input being coupled to said housing, said input being electrically coupled to said control circuit, said input being placed in selective electrical communication with an electronic database for downloading data into said electronic memory, said data comprising a map of a selected building, pre-determined locations in the selected building and a daily schedule pertaining to the predetermined locations in the building.

6. The assembly according to claim 5, wherein said control circuit receives a first input when said transceiver determines said housing has moved within a trigger distance of the predetermined locations in the building.

7. The assembly according to claim 6, further comprising a panic button being coupled to said housing wherein said panic button is manipulated when the user becomes lost or disoriented in the building, said panic button being electrically coupled to said control circuit, said control circuit receiving a second input when said panic button is manipulated.

8. The assembly according to claim 7, wherein said transceiver communicates the physical location of said housing to the extrinsic electronic device assigned to the caregiver when said control circuit receives said second input wherein said panic button is configured to allow the caregiver to locate and assist the user.

9. The assembly according to claim 1, wherein said visual alarm comprises a plurality of light emitters being coupled to said housing wherein each of said light emitters is configured to emit light outwardly therefrom when said alert is turned on.

10. The assembly according to claim 1, further comprising a power supply being positioned within said housing, said power supply being electrically coupled to said control circuit, said power supply comprising at least one battery.

11. An electronic navigation assembly for assisting a disabled user to navigate a building, said assembly comprising:
a housing, said housing having an outer wall having indicia being printed thereon, said indicia comprising shapes and images corresponding to a face of an animal such as a tiger, a bear and other animals that appeal to children;
a clasp being coupled to said housing wherein said clasp is configured to engage an article of clothing to retain said housing on a user;
a control circuit being positioned within said housing;
an electronic memory being positioned within said housing, said electronic memory being electrically coupled to said control circuit;
a transceiver being positioned within said housing, said transceiver being electrically coupled to said control unit, said transceiver being in wireless communication with a global positioning system (gps) thereby facilitating a physical location of said housing to be identified, said transceiver being in wireless communication with an extrinsic electronic device assigned to a caregiver;
an input being coupled to said housing, said input being electrically coupled to said control circuit, said input being placed in selective electrical communication with an electronic database for downloading data into said electronic memory, said data comprising a map of a selected building, pre-determined locations in the selected building and a daily schedule pertaining to the predetermined locations in the building, said control circuit receiving a first input when said transceiver determines said housing has moved within a trigger distance of the predetermined locations in the building;
a display being coupled to said housing, said display being electrically coupled to said control circuit such that said display displays indicia corresponding to a location of said housing superimposed on the map of the selected building wherein said display is configured to assist the user with navigating the selected building;
a panic button being coupled to said housing wherein said panic button is manipulated when the user becomes lost or disoriented in the building, said panic button being electrically coupled to said control circuit, said control circuit receiving a second input when said panic button is manipulated, said transceiver communicating the physical location of said housing to the extrinsic electronic device assigned to the caregiver when said control circuit receives said second input wherein said panic button is configured to allow the caregiver to locate and assist the user;
an alert being coupled to said housing, said alert being electrically coupled to said control circuit, said alert emitting a visual alarm when said control circuit receives said first input to alert the user that the user is approaching one of the predetermined locations, said visual alarm comprising a plurality of light emitters being coupled to said housing wherein each of said light emitters is configured to emit light outwardly therefrom when said alert is turned on; and
a power supply being positioned within said housing, said power supply being electrically coupled to said control circuit, said power supply comprising at least one battery.
